(19) United States
(12) Patent Application Publication
(10) Pub. No.: US 2020/0294553 A1
(43) Pub. Date: Sep. 17, 2020

(54) HARD DRIVE STORAGE DEVICE

(71) Applicant: SHENZHEN ORICO TECHNOLOGIES CO., LTD., Longgang District, Shenzhen, Guangdong (CN)

(72) Inventor: Yeyou Xu, Shenzhen (CN)

(73) Assignee: SHENZHEN ORICO TECHNOLOGIES CO., LTD., Longgang District, Shenzhen, Guangdong (CN)

(21) Appl. No.: 16/082,084

(22) PCT Filed: Dec. 7, 2016
(86) PCT No.: PCT/CN2016/108911

§ 371 Date: Sep. 4, 2018

(30) Foreign Application Priority Data
Mar. 28, 2016 (CN) 201620246414.7

(51) Int. Cl. G11B 33/12; G11B 33/04; H05K 5/02

(52) U.S. Cl. CPC G11B 33/126; H01R 13/6594; H05K 5/0247; G11B 33/0466

(57) ABSTRACT

A hard drive storage device comprises a hard drive enclosure (10) configured to accommodate a hard drive (20), and a hub (30) disposed in the hard drive enclosure (10). The hard drive (20) is electrically connected to the hub (30). The hub (30) comprises two or more USB interfaces (31) arranged at a side wall of the hard drive enclosure (10). The hard drive storage device integrates together a storage functionality of the hard drive and a data interface expansion functionality of the hub, and is easy to use and carry.

### TECHNICAL FIELD

The present disclosure relates to a hard disk (hard drive) storage device.

### BACKGROUND ART

As the technology of electronic products has been growing in the market, host devices (like notebooks or ultrabooks) are becoming thinner and lighter, while the corresponding space for installing data transfer interfaces of the host devices is getting smaller and smaller, and the number of the data transfer interfaces is also limited. Portable storage devices are frequently used in our daily routine, but current portable storage devices on the market typically only offer a single functionality, storage. As such, it would be difficult for the host devices to further provide data transfer interfaces sufficient for other electronic devices to access when the data transfer interfaces of the host devices have been taken up by the storage devices. Needless to say, this would cause inconvenience to daily work.

### DISCLOSURE OF THE INVENTION

The primary purpose of this disclosure is to provide a hard disk storage device, which is designed to integrate the functions of hard disk storage and data interface expansion.

To achieve the foregoing objective, the present disclosure proposes a hard-disk cartridge configured to house a hard-disk body, and a hub disposed within the hard-disk cartridge. The hard disk body is electrically connected with the hub. The hub is provided with at least two USB interfaces. The USB interfaces are disposed on a sidewall of the hard-disk cartridge.

Preferably, the hard disk body is a 2.5-inch hard disk or a 3.5-inch hard disk.

Preferably, the hard disk storage device includes one or more hard disk bodies.

Preferably, the USB interfaces are USB2.0 interfaces or USB3.0 interfaces.

Preferably, the hard-disk cartridge includes a main body. The main body includes one cartridge body. The cartridge body is provided with a housing chamber. The hub is housed in the housing chamber, and the USB interfaces are disposed on two adjacent sidewalls of the cartridge body.

Preferably, the hub is further provided with an external power interface, and the external power interface is disposed on one sidewall of the cartridge body.

Preferably, the main body further includes a fixing frame connected with one side of the cartridge body; each of the hard disk body is disposed in the fixing frame; the hard-disk cartridge further includes a lower cover, with the lower cover being snap-fitted with the fixing frame and the one side of the cartridge body so as to enclose the hub in the housing chamber.

Preferably, the hard-disk cartridge further includes an upper cover, with the upper cover being snap-fitted with the other side of the fixing frame to confine the hard disk body in the fixing frame.

Preferably, the upper cover and the main body are snap-fitted with each other, as well as the lower cover and the main body are snap-fitted with each other.

In the technical solution of this disclosure, the hard disk body and the hub are integrated in the hard-disk cartridge, in which the hard disk body is electrically connected with the hub. At least two USB interfaces are provided on a sidewall of the hard-disk cartridge, so that the hard disk storage device of this disclosure is capable of data interface expansion while playing its role of hard disk storage, and therefore, brings convenience to our work and life.

### DESCRIPTION OF THE DRAWINGS

In order to illustrate the technical solutions of the embodiments in the present disclosure or in the prior art more clearly, figures required in the description of the embodiments or the prior art will be introduced briefly below. Obviously, the figures in the following description merely show some embodiments of the present disclosure. Those ordinarily skilled in the art still can obtain other relevant figures according to the structures shown in these figures, without paying inventive effort.

FIG. 1 is a schematic structural diagram of a hard disk storage device according to an embodiment of the present disclosure;

FIG. 2 is an exploded schematic structural diagram from one view angle of the hard disk storage device of FIG. 1;

FIG. 3 is an exploded schematic structural diagram from another view angle of the hard disk storage device of FIG. 1;

FIG. 4 is an exploded schematic structural diagram from a further view angle of the hard disk storage device of FIG. 1.

### DESCRIPTION OF REFERENCE NUMERALS

TABLE 1

| Reference numeral | Name |
|---|---|
| 10 | Hard-disk cartridge |
| 11 | Upper cover |
| 12 | Main body |
| 13 | Cartridge body |
| 14 | Fixing frame |
| 15 | Housing chamber |
| 16 | Lower cover |
| 20 | Hard disk body |
| 30 | Hub |
| 31 | USB interface |
| 32 | External power interface |

How the purpose of the present disclosure is achieved, and the functional features and advantages of the present disclosure will be further illustrated in combination with embodiments and with reference to the accompanying drawings.

### DETAILED DESCRIPTION OF EMBODIMENTS

Now, the technical solutions of the embodiments of the present disclosure will be described clearly and comprehensively by referring to the accompanying drawings in the embodiments of this disclosure. It is apparent that the embodiments to be described are merely some, but not all, of the embodiments of the present disclosure. All of the other embodiments obtained by those ordinarily skilled in the art from the embodiments of the present disclosure without making an inventive effort will fall within the protection scope claimed in the present disclosure.

It should be noted that all of the directional indications (such as up, down, left, right, front, rear, etc.) in the embodiments of this disclosure are only used to explain the relative location relation, movement and the like between the components in a specific configuration (as shown in the drawings). If the specific configuration changes, change should also take place in the directional indications accordingly.

In the description of the present disclosure, unless otherwise expressly specified and defined, terms like “connect” and “fix” should be understood in a broad sense. For instance, “fix” could mean a fixed connection, a detachable connection, or an integrated connection; it could mean a mechanical connection or an electrical connection; or it could mean a direct connection, or an indirect connection via an intermediate medium, or it could mean an internal communication between two elements or interaction between two elements, unless otherwise expressly defined. The specific meanings of the above-mentioned terms in the present disclosure could be understood by those ordinarily skilled in the art according to specific situations.

In addition, the technical solutions in the embodiments may be combined with one another, but such combination must be achievable for those ordinarily skilled in the art. When the combined technical solutions are contradict or unachievable, it would be accepted that such combined technical solutions neither are existent, nor fall within the scope of protection as claimed in the present disclosure.

The present disclosure proposes a hard disk storage device.

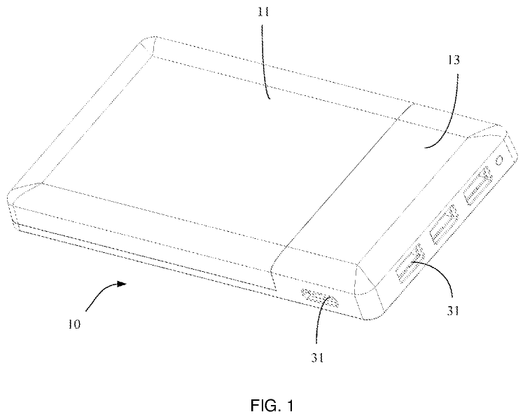

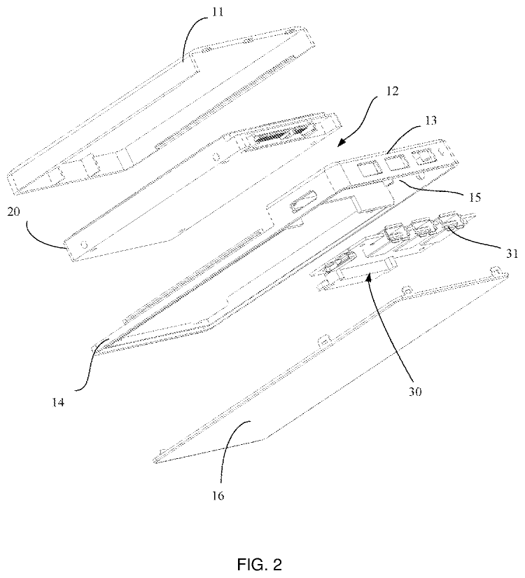

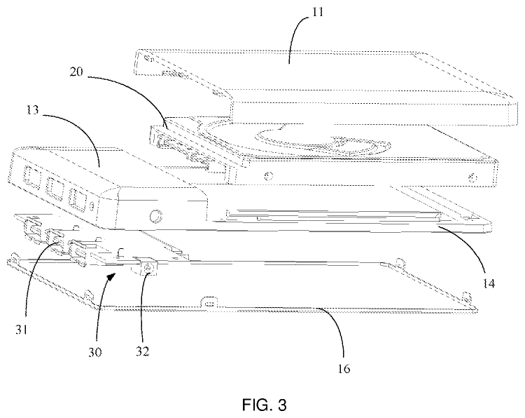

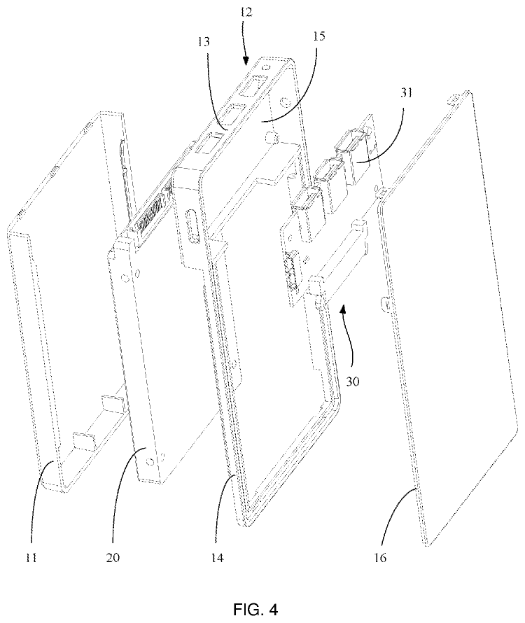

With reference to FIG. 1-FIG. 4, FIG. 1 is a schematic structural diagram of a hard disk storage device according an embodiment of this disclosure; FIG. 2 is an exploded schematic structural diagram from one view angle of the hard disk storage device of FIG. 1; FIG. 3 is an exploded schematic structural diagram from another view angle of the hard disk storage device of FIG. 1; and FIG. 4 is an exploded schematic structural diagram from a further view angle of the hard disk storage device of FIG. 1.

In an embodiment of the hard disk storage device of the present disclosure, the hard disk storage device includes a hard-disk cartridge 10 for housing the hard disk body 20 and a hub 30 disposed within the hard-disk cartridge 10. The hard disk body 20 is electrically connected with the hub 30. The hub 30 is provided with at least two USB interfaces 31. The at least two USB interfaces 31 are disposed on a sidewall of the hard-disk cartridge 10.

It can be understood that the hub 30 includes a main control PCB panel (not denoted) with which a plurality of USB interfaces 31 are connected and the hub 30 may be electrically connected with the hard disk body 20 via a SATA data line. In this embodiment, four USB interfaces 31 are provided. One USB interface 31 may be used to connect with a computer. The other USB interfaces 31 may be used by users. The USB interfaces 31 may be USB 2.0 interfaces or USB 3.0 interfaces. After the hard disk storage device of the present disclosure is connected with a computer, the hub 30 acts as a relay which enables communication between the hard disk body 20 and the computer, and the computer reads and writes the hard disk body 20 through the hub 30. The hard-disk cartridge 10 may be made of plastic materials and can be produced by means of injection molding.

In the technical solution of the present disclosure, the hard disk body 20 and the hub 30 are collectively disposed within the hard-disk cartridge 10, the hard disk body 20 and the hub 30 are electrically connected, and the hard-disk cartridge 10 is provided with a plurality of USB interfaces 31 on its sidewall, so that the hard disk storage device of this disclosure is capable of data interface expansion of the hub 30 while playing its role of hard disk storage, and therefore, brings convenience to our work and life.

The hard disk body 20 may be a 2.5-inch hard disk or a 3.5-inch hard disk. A 2.5-inch hard disk or a 3.5-inch hard disk is frequently used in everyday life. In this embodiment, the hard-disk cartridge 10 is sized to fit the size of the hard disk body 20, so that the hard-disk cartridge 10 has sufficient internal space to accommodate the hard disk body 20.

The hard disk storage device includes one or more hard disk bodies 20. The hard disk bodies 20 may be superposed on one another inside the hard-disk cartridge 10. When provided with a plurality of hard disk bodies 20, the hard disk storage device in the present embodiment also has the function of a disk array.

With reference to FIG. 2 and FIG. 4, specifically, the hard-disk cartridge 10 includes a main body 12. The main body 12 includes a cartridge body 13. The cartridge body 13 is provided with a housing chamber 15. The hub 30 is housed in the housing chamber 15. The USB interfaces 31 are disposed on two adjacent sidewalls of the cartridge body 13.

Four USB interfaces 31 in this embodiment are disposed on two adjacent sidewalls of the cartridge body 13, one of which is provided with one USB interface, the other being provided with three USB interfaces. In using this hard disk storage device, the USB interface 31 on the sidewall of the cartridge body 13 that faces the computer is connected via data lines, while the USB interfaces 31 on the other sidewall of the cartridge body 13 may face a user, so that it would be easy for the user to connect the connection wires of other electronic devices to this hard disk storage device, making it convenient to use the hard disk storage device.

With reference to FIG. 3, the hub 30 is further provided with an external power interface 32. The external power interface 32 is disposed on one sidewall of the cartridge body 13. The hard disk storage device of this embodiment can be powered through the USB interfaces 31. When the data interface of the computer does not output sufficient power, the hard disk storage device may be powered by the external power interface 32 accessing the external mains supply, ensuring the normal use of the hard disk storage device in various conditions.

Further, with reference to FIG. 2 to FIG. 4, the main body 12 further includes a fixing frame 14 connected on one side of the cartridge body 13. The hard disk body 20 is disposed within the fixing frame 14. The hard-disk cartridge 10 further includes an upper cover 11 and a lower cover 16. The lower cover 16 is snap-fitted with the fixing frame 14 and the cartridge body 13 so as to enclose the hub 30 in the housing chamber 15, and the upper cover 11 is snap-fitted with the other side of the fixing frame 14 so as to confine the hard disk body 20 in the fixing frame 14.

In this embodiment, the upper cover 11 and the main body 12 of the hard disk storage device are snap-fitted with each other, as well as the lower cover 16 and the main body 12 are snap-fitted with each other. It is easy to dismount the upper cover 11 and the lower cover 16 from the main body 12. This makes it easy for a user to replace the hard disk main body 20 during use, and can allow a user to operate data reading on different hard disks. Hence, the present hard disk storage device is convenient to use.

The above embodiments are merely the preferred embodiments of the present disclosure and are not intended to limit the patentable scope of the present disclosure. Any equivalent structural modifications made from the description as well as the accompanying drawings, or any direct/indirect uses of the present disclosure in other related technical fields all should fall into the scope of patent protection of the present disclosure under the inventive concept of thee present disclosure.

1. A hard disk storage device, comprising a hard-disk cartridge configured to house a hard disk body, and a hub disposed within the hard-disk cartridge, wherein the hard disk body is electrically connected with the hub, the hub is provided with at least two USB interfaces, and the USB interfaces are disposed on a sidewall of the hard-disk cartridge.

2. The hard disk storage device according to claim 1, wherein the hard disk body is a 2.5-inch hard disk or a 3.5-inch hard disk.

3. The hard disk storage device according to claim 2, comprising one or more hard disk bodies.

4. The hard disk storage device according to claim 1, wherein the USB interfaces are USB2.0 interfaces or USB3.0 interfaces.

5. The hard disk storage device according to claim 1, wherein the hard-disk cartridge comprises a main body, the main body comprises one cartridge body, the cartridge body is provided with a housing chamber, the hub is housed in the housing chamber, and the USB interfaces are disposed on two adjacent sidewalls of the cartridge body.

6. The hard disk storage device according to claim 5, wherein the hub is further provided with an external power interface, and the external power interface is disposed on one sidewall of the cartridge body.

7. The hard disk storage device according to claim 5, wherein the main body further comprises a fixing frame connected with one side of the cartridge body, each of the hard disk body is disposed in the fixing frame, and the hard-disk cartridge further comprises a lower cover, with the lower cover being snap-fitted with the fixing frame and the one side of the cartridge body so as to enclose the hub in the housing chamber.

8. The hard disk storage device according to claim 7, wherein the hard-disk cartridge further comprises an upper cover, with the upper cover being snap fitted with the other side of the fixing frame to confine the hard disk body in the fixing frame.

9. The hard disk storage device according to claim 8, wherein the upper cover and the main body are snap-fitted with each other, as well as the lower cover and the main body are snap-fitted with each other.
